(19) United States
(12) Patent Application Publication
(10) Pub. No.: US 2026/0211177 A1
(43) Pub. Date: Jul. 23, 2026

(54) WAVEGUIDE PHOTODETECTORS FOR REDUCING RETRO-REFLECTION AND INCREASING BANDWIDTH

(71) Applicant: RANOVUS INC., Kanata (CA)

(72) Inventors: Ryan Murray HICKEY, Stittsville (CA); Kyle MURRAY, Fuerth (DE); Douglas J. S. BECKETT, Kanata (CA); Prova Christina GOMES, Ashton (CA); Edgar HUANTE-CERON, Stittsville (CA); Mohammad KARIMI, Ottawa (CA); Hatef SHIRAN, Ottawa (CA)

(21) Appl. No.: 19/139,027

(22) PCT Filed: May 17, 2024
(86) PCT No.: PCT/IB2024/054811

§ 371 Date: Jun. 13, 2025

Related U.S. Application Data
(60) Provisional application No. 63/503,276, filed on May 19, 2023.

(51) Int. Cl. G02B 6/12; G02B 6/122; H10F 30/223; H10F 77/40

(52) U.S. Cl. CPC G02B 6/12004; G02B 6/1223; H10F 30/223; H10F 77/413; G02B 2006/12061; G02B 2006/12123; G02B 2006/12126

(57) ABSTRACT

A waveguide photodetector for reducing retro-reflection and increasing bandwidth is provided. The waveguide photodetector comprises: a waveguide photodiode having: a main waveguide, an absorbing waveguide integrated with the main waveguide, and an input facet at the absorbing waveguide; and an input waveguide for transmitting light to the waveguide photodiode, an input angle between the input waveguide and the input facet comprising an acute interface angle.

### FIELD

The present invention is directed to waveguide photodetectors, and in particular to waveguide photodetectors for reducing retroreflection and increasing bandwidth.

### BACKGROUND

A photodetector generally includes a photodiode that comprise a light-sensitive semiconductor diode that produces current in response to absorption of photons. Photodetectors and/or photodiodes may be discrete devices or into integrated as waveguides into a photonic integrated circuit (PIC). Waveguide photodiodes may generally include a main waveguide for directing light into an absorbing waveguide of the waveguide photodiode, and may be physically located at an end of an input waveguide for delivering input light to the waveguide photodiode, which, for example, may be received from a transmitter in an optical communication system. Both the main waveguide and the absorbing waveguide of the waveguide photodiode may be generally aligned with the input waveguide for directing light into the absorbing waveguide (e.g., which converts the light into electrons and holes (e.g., electron-hole pairs) to generate a current). The input waveguide may be fabricated from silicon or silicon nitride with a dielectric cladding. The main waveguide may be fabricated from silicon with an attached, grown, and/or absorbing waveguide, and the material of the absorbing waveguide may include germanium.

The function of the absorbing waveguide is to convert the optical signal to an electrical signal. The absorbing waveguide is generally connected to positive and negative contacts. The electrical signal may be transmitted to an amplifier on or off a PIC.

The absorbing waveguide is both transmissive and absorbing. In optical or electromagnetic terms, the material has a complex refractive index, having both real and complex components.

In general, when there is a change in a real component of a refractive index of an optical material that is carrying incident light, for example in a waveguide, a reflection will occur in an optical path. Hence, returning to waveguide photodetectors and/or waveguide photodiodes, when respective optical axes of a main waveguide and an input waveguide are coincident, and an input facet of an absorbing waveguide is perpendicular to the input waveguide, a significant amount of light may be reflected back through the input waveguide, the reflected light having a magnitude determined by both the difference in refractive indices between the input waveguide and the absorbing waveguide, and an angle of incidence with respect to the input facet, which, in this instance is 90°. This reflected light may lead to an improper functioning of the waveguide photodetector and/or waveguide photodiode (e.g., as the reflected light is not detected), and the reflected light may be transmitted back through the input waveguide and interfere with a transmitted signal carried by the incident light.

### BRIEF DESCRIPTIONS OF THE DRAWINGS

For a better understanding of the various implementations described herein and to show more clearly how they may be carried into effect, reference will now be made, by way of example only, in which:

FIG. 1 is a schematic illustration of a waveguide photodetector, according to a non-limiting embodiment.

FIG. 2 is a schematic illustration of a waveguide photodetector, according to an alternative non-limiting embodiment.

FIG. 3 is a schematic illustration of a waveguide photodetector, according to yet another alternative non-limiting embodiment.

FIG. 4 is a schematic illustration of a waveguide photodetector, according to yet another alternative non-limiting embodiment.

FIG. 5 is a schematic illustration of a waveguide photodetector, according to yet another alternative non-limiting embodiment.

FIG. 6 is a schematic illustration of a waveguide photodetector that refracts light towards a p-doped semiconductor region, according to yet another alternative non-limiting embodiment.

FIG. 7 is a schematic illustration of a waveguide photodetector that refracts light towards a p-doped semiconductor region, according to yet another alternative non-limiting embodiment.

FIG. 8 depicts an example frequency response of the waveguide photodetector of FIG. 7, as compared to example bandwidth of a waveguide photodetector that refracts light towards an n-doped semiconductor region.

FIG. 9 depicts respective responsivity of a waveguide photodetector that refracts light towards a p-doped semiconductor region, and a waveguide photodetector that does not refract light towards either a p-doped semiconductor region or an n-doped semiconductor region.

FIG. 10 depicts a cross-section through the line A-A′ of the waveguide photodetector of FIG. 1.

FIG. 11 is a schematic illustration of a waveguide photodetector, according to yet another alternative non-limiting embodiment.

### DETAILED DESCRIPTION

The present specification provides a waveguide photodetector comprising: a waveguide photodiode having: a main waveguide, an absorbing waveguide integrated with the main waveguide, and an input facet at the absorbing waveguide; and an input waveguide for transmitting light to the waveguide photodiode, an input angle between the input waveguide and the input facet comprising an acute interface angle. Such an arrangement is understood to prevent and/or reduce retro-reflections from the input facet back down the input waveguide.

The waveguide photodetector may further comprise: an n-doped semiconductor region along a first side of the absorbing waveguide; and a p-doped semiconductor region along a second side of the absorbing waveguide, the second side opposite the first side. The input facet may further form an acute angle with the optical axis, and an interior of the input facet may be angled towards the p-doped semiconductor region, such that light input to the input facet is refracted towards the p-doped semiconductor region. Such an arrangement may result in increased bandwidth capability by the waveguide photodetector.

The present specification further provides a waveguide photodiode comprising: a main waveguide; an absorbing waveguide integrated with the main waveguide, one or more of the absorbing waveguide and the main waveguide having an optical axis; an n-doped semiconductor region along a first side of the absorbing waveguide; a p-doped semiconductor region along a second side of the absorbing waveguide, the second side opposite the first side; and an input facet at the absorbing waveguide, the input facet forming an acute angle with the optical axis, and an interior of the input facet angled towards the p-doped semiconductor region, such that light input to the input facet is refracted towards the p-doped semiconductor region, and the input facet. Such an arrangement may result in increased bandwidth capability by the waveguide photodiode.

Such a waveguide photodiode may be component of a waveguide photodetector, comprising: the waveguide photodiode having: the main waveguide, the absorbing waveguide integrated with the main waveguide, and the input facet at the absorbing waveguide; and the input waveguide for transmitting light to the waveguide photodiode; in these examples, the input angle between the input waveguide and the input facet generally comprising an acute interface angle. Such an arrangement is understood to prevent and/or reduce retro-reflections from the input facet back down the input waveguide.

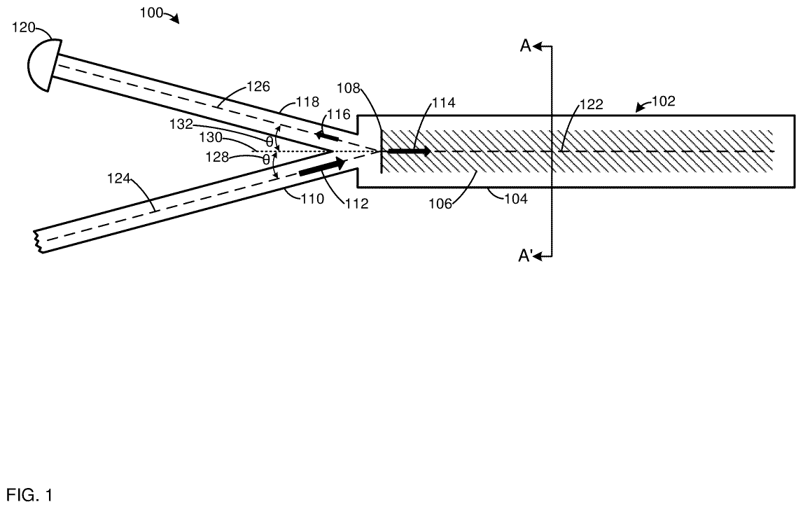

With reference to FIG. 1, a waveguide photodetector 100 is depicted, comprising: a waveguide photodiode 102 comprising: a main waveguide 104, an absorbing waveguide 106, and an input facet 108 at the absorbing waveguide 106. The waveguide photodetector 100 further comprises: an input waveguide 110 for transmitting light 112 to the waveguide photodiode 102, which is received at the input facet 108, and directed and/or transmitted and/or refracted into the absorbing waveguide 106 via the main waveguide 104, as indicated by transmitted light 114. A portion of the light 112 may be reflected from the input facet 108, as indicated by reflected light 116. For clarity, the input facet 108 is represented by a line, however the input facet 108 is understood to comprise an end of the absorbing waveguide 106 at which the light 112 is received. Furthermore, the light 112 may be interchangeably referred to hereafter as incident light 112, for example incident on the input facet 108.

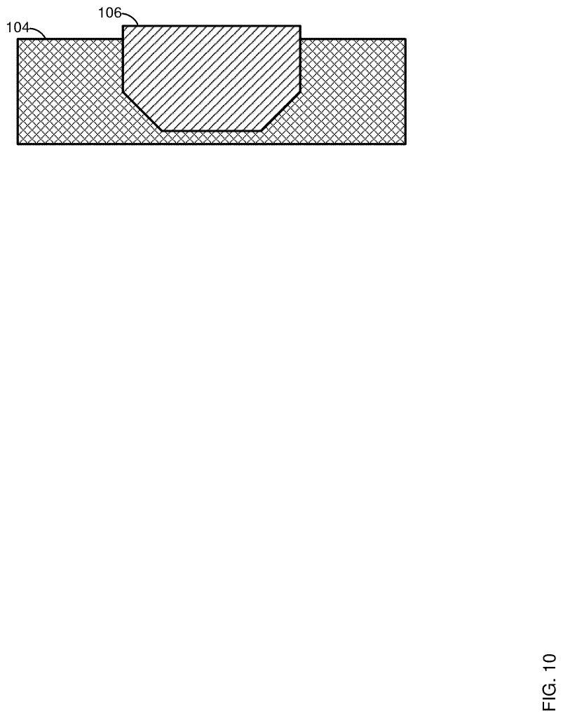

Furthermore, it is understood that the absorbing waveguide 106 and the main waveguide 104 form an integrated structure. Put another way, the absorbing waveguide 106 is integrated with the main waveguide 104. For example, attention is briefly directed to FIG. 10, which depicts an example cross-section of the waveguide photodiode 102 through a line A-A′ (e.g., of FIG. 1), and which illustrates that the absorbing waveguide 106 may be formed in a trough and/or groove and trench (e.g., an anisotropic etch feature) of the main waveguide 104. With attention directed back to FIG. 1, it further understood that the main waveguide 104 may be located around the absorbing waveguide 106, such that the main waveguide 104 is also at, and/or around, the input facet 108 of the absorbing waveguide 106. Hence, the incident light 112 from the input waveguide 110 may enter the main waveguide 104 and be incident on the input facet 108 of the absorbing waveguide 106. As such, certain solutions for reducing reflections from the input facet 108, such as anti-reflection coatings, are not possible in the integrated structure of waveguide photodetectors and/or waveguide photodiodes as provided herein.

It is hence further understood that the main waveguide 104 generally assists at directing the incident light 112 into the absorbing waveguide 106, via the input facet 108, and furthermore the absorbing waveguide 106 both conveys the transmitted light 114 (e.g., waveguide function) and converts the transmitted light 114 into a current (e.g., and/or electron-hole pairs). As such, it is understood that the absorbing waveguide 106 is formed from any suitable photodiode material, including, but not limited to germanium; however any suitable type of photodiode material is within the scope of the present specification, including, but not limited to, gallium arsenide, indium gallium arsenide, and the like, amongst other possibilities. It is further understood that a length of the absorbing waveguide 106 (e.g. along the optical axis 122) may be selected such that the transmitted light 114 is substantially absorbed before reaching an and of the absorbing waveguide 106 opposite to that of the input facet 108.

As the waveguide photodetector 100 may be used in optical communication systems, it is understood that the incident light 112, may be at a wavelength that is compatible with such optical communication systems, such as about 1310 nm, though the waveguide photodetector 100 may be used with other wavelengths and/or in other types of systems.

Furthermore, as the waveguide photodetector 100 may be a component of a photonic integrated circuit (PIC), it is understood that references herein to certain optical properties of materials used for certain components of the waveguide photodetector may be affected by being components of a PIC. For example, in the context of optical waveguides, the relevant index of refraction of the optical materials is referred to as a mode index. Hence, any references to an index of refraction of a material as used herein, are understood to refer to a mode index, and vice versa.

While the light 112, 114, 116 is drawn as a discrete arrows for simplicity, it is understood that the light 112, 114, 116 may comprise modulated light and/or an optical signal with data encoded therein, and that the transmitted light 114 is to be detected by the absorbing waveguide 106 and converted to current by the absorbing waveguide 106. Indeed, the input waveguide 110 may be an end of a longer waveguide (not depicted), and/or the input waveguide 110 may be in optical communication with such a longer waveguide. Regardless, in use, the input waveguide 110 may be in optical communication with a transmitter, of an optical communication system, that is transmitting data to the waveguide photodetector 100 in form of modulated incident light 112. Indeed, the waveguide photodetector 100 may be a component of a receiver (e.g., a PIC receiver) in such an optical communication system. While not depicted, the waveguide photodetector 100 is generally understood to include contacts (e.g., n-doped semiconductor and p-doped semiconductor, such as silicon, though any suitable semiconductor is within the scope of the present specification) for receiving current generated by the absorbing waveguide 106. As the transmitted light 114 is understood to be modulated, the current generated by the absorbing waveguide 106 may also be modulated, such that the data encoded in the incident light 112 is determined from other components (not depicted) that receive the modulated current.

As depicted, the waveguide photodetector 100 may optionally comprise an output waveguide 118 that extends from the main waveguide 104, and the output waveguide 118 may convey the reflected light 116 from the input facet 108. In general, a sum of intensity of the transmitted light 114 (e.g., immediately upon entering the input facet 108) and the reflected light 116 is understood to be about the same as intensity of the light 112.

To absorb the reflected light 116, and when such an output waveguide 118 is present, the waveguide photodetector 100 may optionally include a light dump 120 (e.g., a device for absorbing light), for example at an end of the output waveguide 118 that is opposite to a respective end at the absorbing waveguide 106.

However, the output waveguide 118 may comprise any suitable material and/or structure to one or more of scatter, disperse and absorb the reflected light 116, so that the reflected light 116 does not return back to the input waveguide 110.

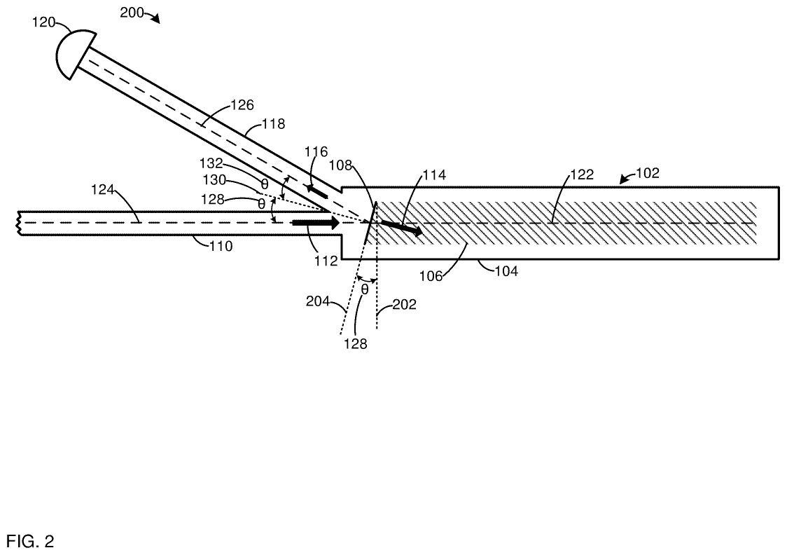

For clarity, and to facilitate discussion of geometric relationships between components of the waveguide photodetector 100, respective optical axes 122, 124, 126 of the waveguides 104 (and/or the waveguide 106), 110, 118 are also depicted, and it is understood that light carried by the waveguides 104, 106, 110, 118 may generally be centered on such optical axes 122, 124, 126 (e.g., unless refracted away from the optical axis 122, as described with respect to FIG. 2). It is further understood that the optical axes 122, 124, 126 may also define respective longitudinal axes of the waveguides 104, 106, 110, 118.

In prior art waveguide photodetectors and/or waveguide photodiodes, the optical axes 122, 124 of the waveguides 104, 110 would generally be coincident, such that the incident light 112 would impinge on the input facet 108 at a normal and/or 90° angle, and hence the reflected light 116 would be reflected back down the input waveguide 110. This generally causes both the intensity of the transmitted light 114 to be reduced, which may cause the current generated by the absorbing waveguide 106 to be reduced, and which may cause errors in detecting data embedded in the incident light 112. Furthermore, when the reflected light 116 is reflected back down the input waveguide 110, the reflected light 116 is reflected back through the optical communication system toward the transmitter that originated the incident light 112, and the reflected light 116 may generally interfere with proper transmission of the communication signal and/or data encoded in the incident light 112. In bulk optics, solutions such an anti-reflection coating may be used to reduce such reflections, for example as applied to an input surface of an absorbing photodiode medium to reduce the reflections. However, in the case of waveguide photodetectors and/or waveguide photodiode as provided herein, such anti-reflection coatings are not possible.

Hence, to obviate this problem (e.g., and without access to anti-reflection coatings as a solution), an acute input interface angle 128 (also indicated as “Θ” in FIG. 1) between the input waveguide 110 and the input facet 108 generally comprises an acute interface angle (e.g., less than 90°) and, more particularly, the acute input interface angle 128 (e.g., the acute interface angle) may be in a range of about 8° and about 65°.

Furthermore, it is understood that the acute input interface angle 128 (e.g., the acute interface angle) may be defined as being between the optical axis 124 of the input waveguide 110 and a normal 130 to the input facet 108.

Indeed, as depicted in FIG. 1, the acute input interface angle 128 (e.g., the acute interface angle) may be between the respective optical axes 122, 124 of the waveguides 104, 106 and the input waveguide 110, and the input facet 108 is understood to be about perpendicular to the optical axis 122 of the waveguides 104, 106, such that the normal 130 to the input facet 108 and the optical axis 122 of the waveguides 104, 106 are coincident.

As also depicted in FIG. 1, the respective optical axes 122, 126 of the main waveguide 104 and the output waveguide 118 is at an output angle 132 that is the same as the acute input interface angle 128 (e.g., the acute interface angle), for example according to angle of incidence being equal to angle of reflection. In particular, the output waveguide 118 is also at the same acute interface angle as the input waveguide 110, but in a direction of the reflected light 116. It is furthermore understood that, like the acute input interface angle 128, the output angle 132 may be between the optical axis 126 of the output waveguide 118 and the normal 130 to the input facet 108.

It is further understood that the materials of the waveguides 104, 110, 118 and the absorbing waveguide 106 have indices of refraction, which may affect the intensity of the transmitted light 114 and the reflected light 116. For example, the input waveguide 110 may comprise silicon and/or silicon nitride, for example with a dielectric cladding, and, when made of silicon, the input waveguide 110 may have a mode index (e.g., index of refraction) of about 2.4 at a wavelength of the incident light 112 of 1310 nm. The output waveguide 118 may similarly comprise silicon and/or silicon nitride, for example with a dielectric cladding, and, when made of silicon, the input waveguide 110 may have a mode index (e.g., index of refraction) of about 2.4 at a wavelength of the incident light 112 of 1310 nm. In general, the waveguides 110, 118 may comprise the same material and/or materials, and/or be components of a PIC receiver.

The main waveguide 104 may comprise silicon and/or comprise the same material and/or materials as the waveguides 110, 118. Indeed, all three of the waveguides 104, 110, 118 may comprise the same material and/or materials, and/or be components of a PIC receiver, such that all three of the waveguides 104, 110, 118 may comprise a same index of refraction and/or mode index, and hence there are no optical interfaces therebetween, and/or no light is refracted and/or reflected from interfaces between the waveguides 104, 110, 118. Furthermore, at a PIC, the waveguides 104, 110, 118 may be integrated with each other.

The absorbing waveguide 106, however, generally comprises a waveguide photodiode material, including, but not limited to germanium, having a mode index (e.g., index of refraction) of about 4.1 (e.g., a real portion of the mode index) at a wavelength of the incident light 112 of 1310 nm. The absorbing waveguide 106 may be attached and/or grown and/or embedded at the main waveguide 104. The mode index of absorbing waveguide 106 is furthermore understood to have a significant complex portion (e.g., less than about 0.1 at a wavelength of the incident light 112 of 1310 nm).

As the input waveguide 110 and the absorbing waveguide 106 generally have different indices of refraction and/or mode indices, when the incident light 112 impinges on the input facet 108, the incident light 112 will be at least refracted into the absorbing waveguide 106 as the transmitted light 114, and, in some examples, depending on the acute input interface angle 128, a portion of the incident light 112 will be reflected from the input facet 108 as the reflected light 116.

In particular, the acute input interface angle 128 (e.g., the acute interface angle) may be selected such that the acute input interface angle 128 is at a Brewster angle, for example to minimize and/or eliminate the reflected light 116, and so that the transmitted light 114 is transmitted along (e.g., parallel to) the optical axis 122 of the waveguides 104, 106.

For example, the input waveguide 110 (e.g., a material thereof) may have a first index of refraction and/or mode index of “n1”, and the absorbing waveguide 106 (e.g., a material thereof) may have a second index of refraction and/or mode index of “n2”, and the acute input interface angle 128 (e.g., the acute interface angle) may be determined from: arctan(n2/n1), or the formula for determining a Brewster angle. Such an example assumes that the main waveguide 104 is integrated with the input waveguide 110, and both waveguides 104, 110 are fabricated from a same material and hence have a same, and/or about the same, index of refraction and/or mode index of “n1”.

For example, using n1=2.4 for silicon (e.g., the input waveguide 110 and the main waveguide 104 comprises silicon), and n2=4.1 (e.g., the absorbing waveguide 106 comprises germanium), the acute input interface angle 128 may be selected to be at a Brewster angle of about 30° (e.g., arctan(2.4/4.1)).

Indeed, the closer to the Brewster angle of the acute input interface angle 128, and/or the further from 90°, the more the reflected light 116 may be reduced. As such, the waveguide photodetector 100 reduces retro-reflections from the input facet 108, at least relative to prior art waveguide photodetectors, where light is incident at 90° to an input facet of a waveguide photodiode.

While particular materials and/or particular indices of refraction and/or particular mode indices are described herein, it is understood that the various components of the waveguide photodetector 100 may be fabricated from any suitable materials and have any suitable indices of refraction and/or mode indices. It is furthermore understood that the indices of refraction and/or mode indices may vary according to the materials used for the waveguide photodetector 100 and/or according to a wavelength of the incident light 112. Hence, the various angles described throughout the present specification may vary depending on such factor. Hence, any suitable combination of materials, indices of refraction, mode indices, wavelengths of light, and angles are within the scope of the present specification. Put another way, while components of the waveguide photodetector 100 have been described with respect to certain materials and optical properties, components of the waveguide photodetector 100 may comprise any suitable materials and associated optical properties

Furthermore, the waveguide photodetector 100 may be fabricated in any suitable manner (e.g., using photolithographic methods), for example as a component of a PIC receiver, and at least the waveguides 104, 110 and the absorbing waveguide 106, and the acute input interface angle 128 may be positioned accordingly using a Brewster angle. Indeed, when the acute input interface angle 128 comprises a Brewster angle, the output waveguide 118 (e.g., and/or the light dump 120) may be optional and/or omitted, assuming the reflected light 116 is minimized and/or eliminated. In some of these examples, however, as manufacturing techniques are understood to have tolerances that may cause the acute input interface angle 128 to be close to, but not exactly, the Brewster angle, the output waveguide 118 (e.g., and/or the light dump 120) may be included to carry away and/or absorb, from the input facet 108, even a small amount of resulting reflected light 116.

Furthermore, waveguide photodiodes as presently provided may have other geometric configurations.

For example, attention is next directed to FIG. 2, which depicts a waveguide photodetector 200 that is substantially similar to the waveguide photodetector 100, with like components having like numbers, but the geometric arrangement of the components of the waveguide photodetector 200 is different from the geometric arrangement of the components of the waveguide photodetector 100, though a same effect is achieved.

In particular, respective optical axes 122, 124 of the waveguides 104, 106, and the input waveguide 110 of the waveguide photodetector 100, are coincident, but the input facet 108 forms the acute input interface angle 128 (e.g., the acute interface angle) with a line 202 about perpendicular to the optical axis 122 of the waveguides 104, 106. For clarity, a line 204 extending from the input facet 108, and coincident with the input facet 108, is also depicted to better illustrate the angle of the input facet 108. Furthermore, while as depicted the angle of the input facet 108 is defined with respect to the line 202 about perpendicular to the optical axis 122 of the waveguides 104, 106, the angle of the input facet 108 may be defined in other ways, for example relative to the optical axis 122 of the waveguides 104, 106.

Put yet another way, at the waveguide photodetector 200, the input waveguide 110 and the input facet 108 are at the acute input interface angle 128 (e.g., the acute input interface angle 128 being between the optical axis 124 of the input waveguide 110 and a normal 130 to the input facet 108), but the input facet 108 is angled with respect to the optical axis 124 of the input waveguide 110 (e.g., rather than angling the input waveguide 110 as in the waveguide photodetector 100). As depicted, the transmitted light 114 is refracted at an angle to the optical axis 122, for example rather than along the optical axis 122, as in the waveguide photodetector 100. In particular, the transmitted light 114 may be refracted towards a contact of the absorbing waveguide 106, such as an n-doped semiconductor region or a p-doped semiconductor region. It is further understood that a width of the absorbing waveguide 106 (e.g. perpendicular to the optical axis 122) may be selected such that the transmitted light 114 is substantially absorbed before reaching an edge of the absorbing waveguide 106.

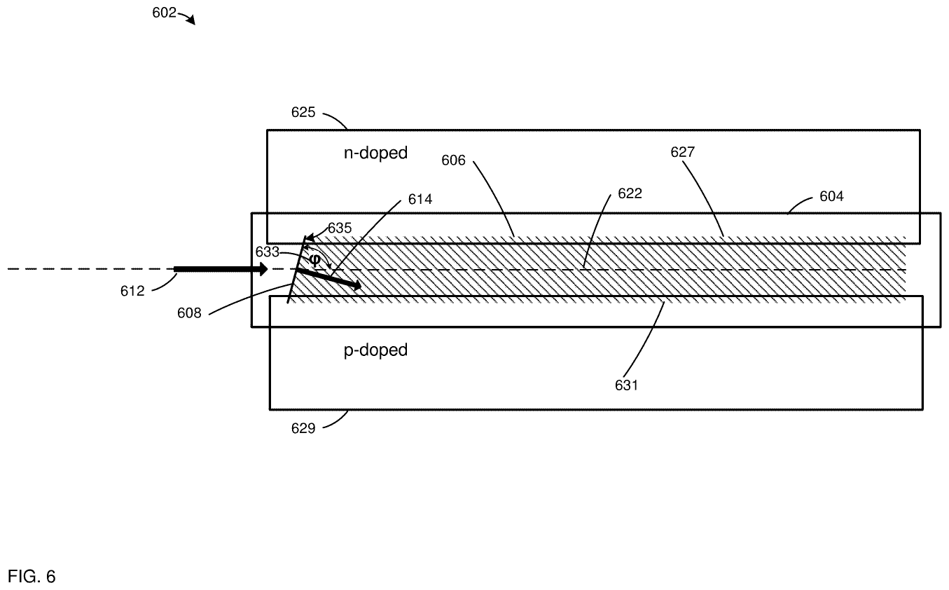

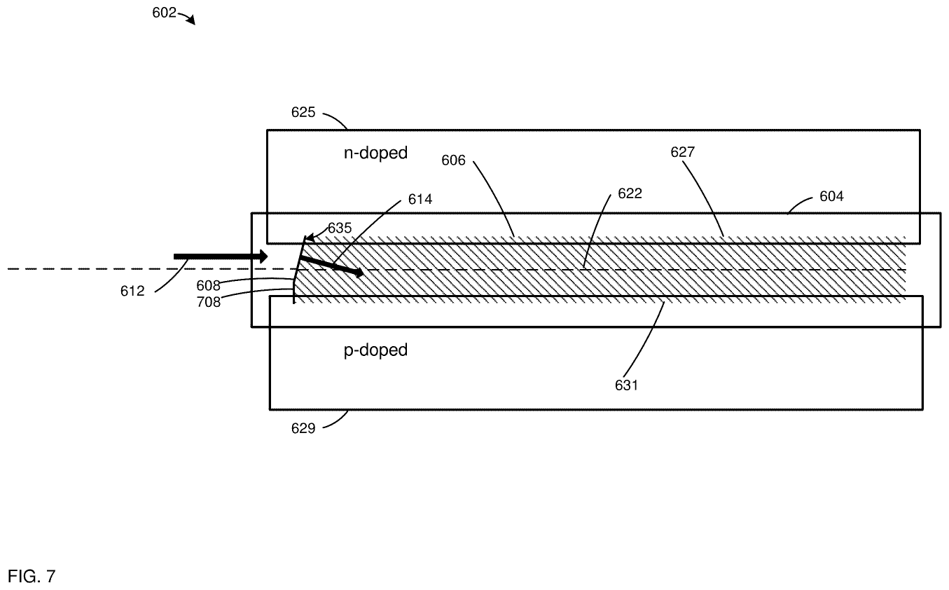

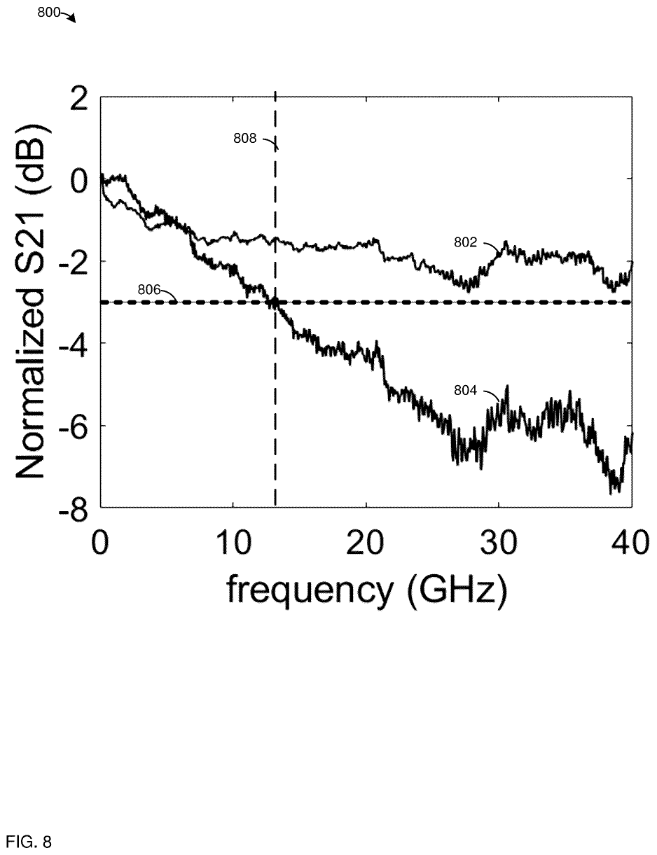

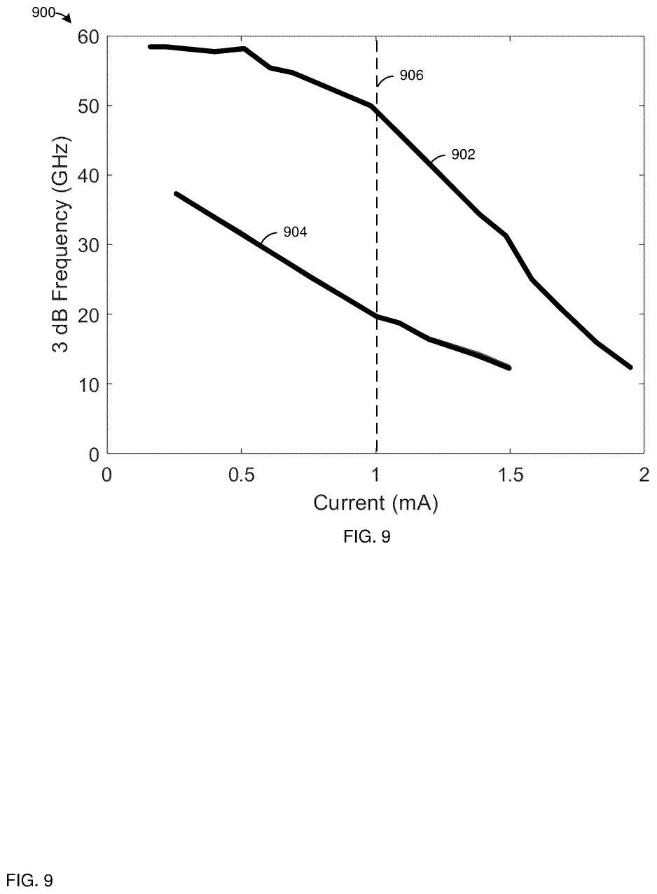

As will be described in further detail below with respect to FIG. 6, FIG. 7, FIG. 8 and FIG. 9, certain advantages may be realized by selecting the geometry of the waveguide photodetector 200 such that the transmitted light 114 is refracted towards a p-doped semiconductor region that comprises a contact of the absorbing waveguide 106.

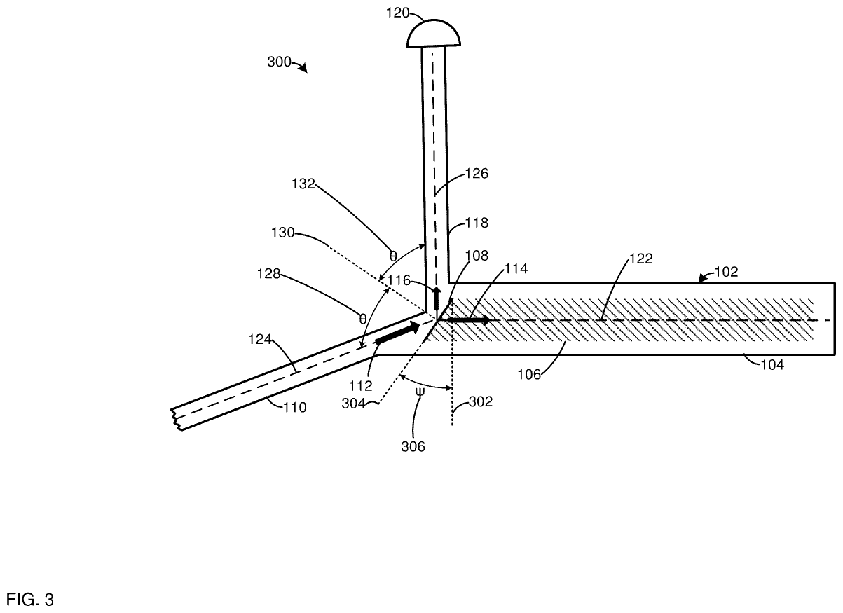

The examples of FIG. 1 and FIG. 2 may be combined. For example, attention is next directed to FIG. 3, which depicts a waveguide photodetector 300 that is substantially similar to the waveguide photodetector 100, and/or the waveguide photodetector 200, with like components having like numbers, but the geometric arrangement of the components of the waveguide photodetector 300 is a combination of the geometric arrangement of the components of the waveguide photodetector 100, and the waveguide photodetector 200, though a same effect is achieved.

In particular, the angles 128, 132, are again both acute angles (e.g., also indicated as “θ” in FIG. 3), and are generally the same, relative to at least the normal 130 to the input facet 108, for example according to angle of incidence being equal to angle of reflection.

Furthermore, like the waveguide photodetector 100, the input waveguide 110 is angled with respect to the optical axis 122 of the waveguides 104, 106, though such an angle may be selected based on a value of the angles 128, 132, and, as will next be explained, an angle of the input facet 108.

For example, like the waveguide photodetector 200, the input facet 108 forms an angle 306 (e.g., also indicated as “ψ” in FIG. 3), with a line 302 about perpendicular to the optical axis 122 of the waveguides 104, 106. For clarity, a line 304 extending from the input facet 108, and coincident with the input facet 108, is also depicted to better illustrate the angle 306 of the input facet 108.

However, unlike the waveguide photodetector 200, the angle 306 is not the same as the angles 128, 132. Rather, the angle 306 is different from the angles 128, 132. However, the angles 128, 132, 306 may all still be selected such that the angle 128 comprises a Brewster angle, so that the transmitted light 114 is refracted along the optical axis 122 of the waveguides 104, 106. Alternatively, the angles 128, 132, 306 may all still be selected such that the transmitted light 114 is refracted towards a particular contact of the waveguide photodiode 102, such as an n-doped semiconductor region or a p-doped semiconductor region

Put another way, at the waveguide photodetector 300, the input waveguide 110 is at the acute input interface angle 128 with the input facet 108, and the input facet 108 forms the acute angle 306 with the line 302 about perpendicular to the optical axis 122 of the waveguides 104, 106, the acute angle 306 different from the acute input interface angle 128, and furthermore the respective optical axes 124, 122 of the input waveguide 110 and the waveguides 104, 106 are not coincident.

Indeed, the waveguide photodetector 300 illustrates the flexibility of waveguide photodetectors provided herein. For example, for certain manufacturing techniques, the depicted “low” angle of the optical axis 124 of the input waveguide 110 relative to the line 304 (e.g., which may be between about 20° and about 35°), may be more suitable than larger angles, though any suitable angles are within the scope of the present specification.

As previously described, the waveguide photodetectors 100, 200, 300 may be manufactured using photolithographic methods, which may generally result in corners of components of the waveguide photodetectors 100, 200, 300 being rounded. In such examples, when the corners are sufficiently rounded, such rounded corners may cause portions of one or more of the waveguides 104, 110, 118 to be absent and/or may interfere with the light 112, 114, 116. To address this issue, during manufacture, photolithography compensation structures may be placed at one or more corners to compensate for the rounding.

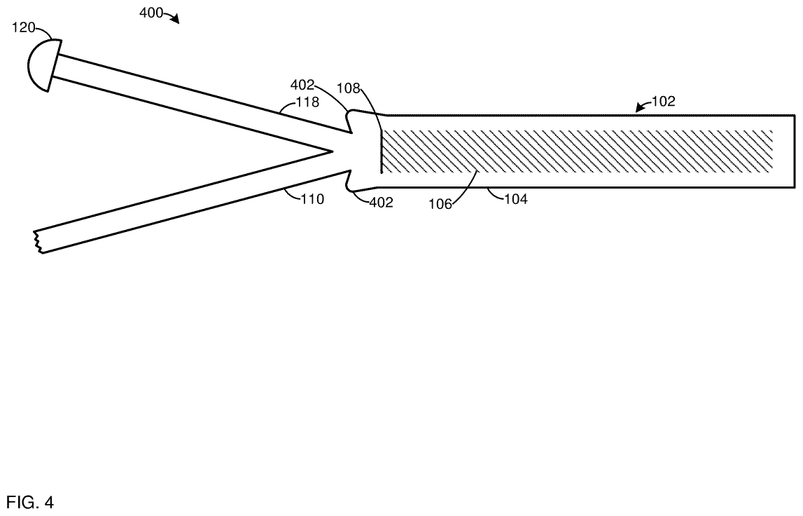

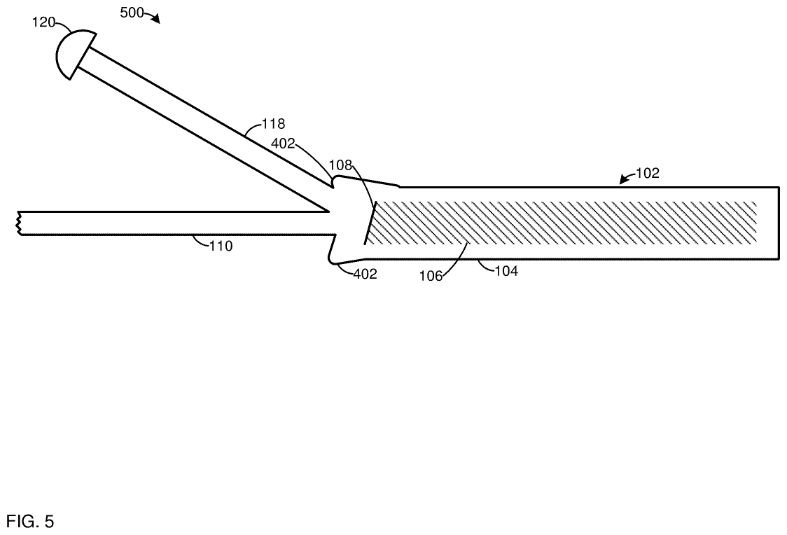

For example, attention is next directed to FIG. 4 and FIG. 5, which respectively depict waveguide photodetectors 400, 500, that are respectively substantially similar to the waveguide photodetectors 100, 200, with like components having like numbers. It is furthermore understood that while the light, angles and optical axes of the waveguide photodetectors 100, 200, are not depicted in FIG. 4 and FIG. 5 for simplicity, such light, angles and optical axes may nonetheless be present at the waveguide photodetectors 400, 500.

In particular, the waveguide photodetectors 400, 500 are respectively substantially similar to the waveguide photodetectors 100, 200, but respective corners of respective main waveguides 104 that are closest to the waveguides 110, 118 are rounded and/or expanded outwards using photolithography compensation structures 402, relative to the corresponding corners of the respective main waveguides 104 of the waveguide photodetectors 100, 200. Such photolithography compensation structures 402 may ensure that no light leaks out of the waveguide photodetectors 400, 500, and/or minimizes such leakage, and/or that any rounding of such corners does not result in narrowing of the respective main waveguides 104 in the region of the input facet 108, and/or that any rounding of such corners does not interfere with the light 112, 114, 116.

While a similar example is not provided with respect to the waveguide photodetector 300, the waveguide photodetector 300 may be similarly adapted to include photolithography compensation structures.

It is furthermore, understood that waveguide photodiodes as provided herein may have input facets that are angled in a particular direction, for example to refract incident light towards a p-doped semiconductor region, to improve bandwidth and/or responsivity, as is next described.

For example, attention is next directed to FIG. 6, which depicts a waveguide photodiode 602, that is substantially similar to the waveguide photodiode 102 of FIG. 2, with like components having like numbers, but in a “600” series, rather than a “100” series. In particular, the waveguide photodiode 602 is configured to refract transmitted light towards a p-doped semiconductor region as is next described.

Furthermore, while the waveguide photodiode 602 is depicted without a remainder of a waveguide photodetector, the waveguide photodiode 602 may be a component of the waveguide photodetector 200 of FIG. 2, a component of the waveguide photodetector 300 of FIG. 3, and/or a component of the waveguide photodetector 500 of FIG. 5, and/or any of the waveguide photodetectors 200, 300, 500 may be adapted to include certain features of the waveguide photodiode 602, as is next described. In particular, any of the waveguide photodetectors 200, 300, 500 may be adapted to refract transmitted light towards a p-doped semiconductor region.

In particular, while not depicted, the waveguide photodiode 602 may be provided with an input waveguide, similar to the input waveguide 110 of FIG. 2 (e.g., and integrated with the main waveguide 604, similar to as depicted in FIG. 2), and/or an output waveguide, similar to the output waveguide 118 of FIG. 2 (e.g., and optionally with an optional light dump, similar to the light dump 120). The waveguide photodiode 602 may be further adapted to include photolithography compensation structures, such as the photolithography compensation structures 402 of FIG. 5. Alternatively, or in addition, a waveguide photodetector into which the waveguide photodiode 602 is incorporated may have a geometry similar to the waveguide photodetector 300.

As depicted, the waveguide photodiode 602 comprises: a main waveguide 604 and an absorbing waveguide 606. The absorbing waveguide 606 is furthermore understood to comprise an input facet 608 that is angled according to a particular configuration as described herein.

For clarity, incident light 612 and refracted (e.g., transmitted) light 614 are also depicted, and while reflected light (e.g., similar to the reflected light 116 of FIG. 2) is not depicted, such reflected light may also be present (e.g., and not reflected in a direction of the incident light 612). For clarity, an optical axis 622 of the main waveguide 604 and/or the absorbing waveguide 606 is also depicted.

Also depicted in FIG. 6 are contacts of the waveguide photodiode 602. For example, as depicted, such contacts comprise: an n-doped semiconductor region 625 along a first side 627 of the absorbing waveguide 606; and a p-doped semiconductor region 629 along a second side 631 of the absorbing waveguide 606, the second side 631 opposite the first side 627, for example relative to the optical axis 622.

As depicted, while optional, there may be some overlap between the doped semiconductor regions 625, 629 and the absorbing waveguide 606; such overlap may depend on a width (e.g., perpendicular to the optical axis 622) of the absorbing waveguide 606. In a particular example, and when the absorbing waveguide 606 comprises Ge, and the doped semiconductor regions 625, 629 may comprise, respectively, n-doped silicon and p-doped silicon, the absorbing waveguide 606 may be between about 400 nm and about 900 nm wide, and the doped semiconductor regions 625, 629 may overlap the absorbing waveguide 606 by about 50 nm to about 100 nm. It is furthermore understood, however, that the depicted overlap may be optional, and the doped semiconductor regions 625, 629 may be adjacent to, and contacting, the respective sides 627, 631.

As photons of the refracted light 614 are absorbed by the absorbing waveguide 606, the material of the absorbing waveguide 606, such as Ge, is excited, generating electrons and holes (e.g., electron-hole pairs). Furthermore, electrons are generally understood to migrate towards the n-doped semiconductor region 625 and the holes are generally understood to migrate towards the p-doped semiconductor region 629, and the resulting current is measured by a current measuring device (not depicted). The current may be assisted via a voltage bias placed across absorbing waveguide 606, for example between the doped semiconductor regions 625, 629, though such a voltage bias may be optional. Furthermore, as the incident light 612 may be modulated due to encoded data, the refracted light 614 may also be modulated, and hence the resulting current may also be modulated.

Attention is again directed to the input facet 608, which, as depicted, forms an acute angle 633 (e.g., less than 90°, and also indicated as φ in FIG. 6) with the optical axis 622. Furthermore, an interior side 635 of the input facet 608 is angled towards the p-doped semiconductor region 629, such that the incident light 612 input to the input facet 608 is refracted towards the p-doped semiconductor region 629, for example as illustrated in FIG. 6 by way of the refracted light 614 being directed towards the p-doped semiconductor region 629.

While the geometry of the input facet 608 is described with respect to the acute angle 633, the geometry of the input facet 608 may be described in other ways, such as with respect to an angle between the input facet 608 and a line perpendicular to the optical axis 622 of the waveguides 604, 606, similar to the lines 202, 302. Indeed, such an angle is also understood to be acute, and again with the interior side 635 of the input facet 608 angled towards the p-doped semiconductor region 629.

It is further understood that, while in the example of FIG. 6 the input facet 608 is across an entire end of the absorbing waveguide 606 (e.g., an end of the absorbing waveguide 606 at which the incident light 612 is received), in other examples, the input facet 608 may be across only a portion of such an end of the absorbing waveguide 606 at which the incident light 612 is received.

For example, attention is next directed to FIG. 7, which is substantially similar to FIG. 6, with like components having like numbers. It is furthermore understood that while the acute angle 633 is not indicated in FIG. 7 for clarity, the input facet 608 is still angled at the acute angle 633, similar to as described with respect to FIG. 6. However, in FIG. 7, in contrast to FIG. 6, the input facet 608 is across only a portion of an end of the absorbing waveguide 606 at which the incident light 612 is received, with a remaining portion 708 of the end being about perpendicular to the optical axis 622. Furthermore, the incident light 612 is arranged (e.g., using an input waveguide) to be incident on about a center of the angled input facet 608; hence, while the incident light 612 is still parallel to the optical axis 622, the incident light 612 may not be along the optical axis 622.

It is furthermore understood that the angled input facet 608 may be closer to the n-doped semiconductor region 625 than the p-doped semiconductor region 629, and/or the remaining portion 708 is closer to the p-doped semiconductor region 629 than the n-doped semiconductor region 625. Put another way, as depicted, the remaining portion 708 is located between the angled input facet 608 and the p-doped semiconductor region 629.

The arrangement of FIG. 7 is provided to illustrate that various alternatives to the shape and/or location of the input facet 608 is within the scope of the present specification and indeed any of the waveguide photodetectors 200, 300, 500 may be similarly adapted.

As will be described below with respect to FIG. 8 and FIG. 9, testing and/or modeling of the waveguide photodiode 602 (e.g., whether as in the configuration of FIG. 6 or the configuration of FIG. 7) has shown that the waveguide photodiode 602 is more efficient than when an input facet of a waveguide photodiode is angled in a direction opposite of that depicted in FIG. 6 (or FIG. 7), such that refracted light is directed towards an n-doped semiconductor region. Similarly testing and/or modeling of the waveguide photodiode 602 (e.g., whether as in the configuration of FIG. 6 or the configuration of FIG. 7) has shown that the waveguide photodiode 602 is more efficient than when an input facet 608 is at 90° to an optical axis of a main waveguide (e.g., such that the refracted light is directed along the optical axis of a main waveguide).

This effect may be understood with respect to migration of electrons and holes in waveguide photodiode materials. For example, using Ge as a particular example material of the absorbing waveguide 606, electrons are understood to have a higher mobility than holes in Ge (e.g., and such mobilities are also generally a function of temperature). A time for electrons and holes to reach the respective doped semiconductor regions 625, 629, for example from a location in the absorbing waveguide 606 where an electron-hole pair is generated, may be referred to a transit time. Hence, in the configuration depicted in FIG. 6 and/or FIG. 7, as the refracted light 614 is directed towards the p-doped semiconductor region 629, holes and electrons may be generated closer to the p-doped semiconductor region 629, for example as compared to when the refracted light 614 is directed towards the n-doped semiconductor region 625, and/or as compared to when the refracted light 614 is directed along the optical axis 622. As such, the acute angle 633 may be selected such that the transit times for the electrons and the holes generated at the absorbing waveguide 606 via the refracted light 614 have about a same transit time. Doing so may cause the waveguide photodiode 602 to have higher bandwidth and higher responsivity as compared to when the refracted light 614 is directed towards the n-doped semiconductor region 625 or along the optical axis 622.

Put another way, the refracted light 614 generates electron-hole pairs; as the mobility of electrons are much higher than mobility of holes in Ge (e.g., the holes move slower than the electrons), angling of the refracted light 614 towards the p-type region 629, which receives the holes, may cause the holes to be formed closer the p-type region 629. As such, the electrons and holes may arrive at their respective doped semiconductor regions 625, 629 at about a same time.

However, as measuring transit time may be challenging, testing and/or modelling of various values of the acute angle 633 has shown that a value of about 45° may result in a maximum bandwidth. Such testing and/or modelling has shown that other values of the acute angle 633 may result in higher bandwidth and higher responsivity as compared to when the refracted light 614 is directed towards the n-doped semiconductor region 625 or along the optical axis 622. For example, the acute angle 633 may be between about 30° and about 70°. In particular examples, the acute angle 633 may be between about 45° and about 60°. However, any suitable angles are within the scope of the present specification, and may be selected heuristically to balance bandwidth requirements and manufacturing requirements of waveguide photodetectors of the present specification.

In particular, it is understood that data encoded into the incident light 612, carried by an input waveguide, may have a particular bandwidth, and the waveguide photodiode 602 may detect such data in the form of modulated current across the doped semiconductor regions 625, 629.

Attention is next directed to FIG. 8, which depicts a graph 800 showing a frequency response of the waveguide photodetector of FIG. 7, and in particular intensity 802, 804 of signals as a function of bandwidth of data encoded into incident light (e.g., as indicated by frequency of data encoded into the incident light). Both intensities 802, 804 are defined with respect to an S21 transmission coefficient. In particular, the intensity 802 was determined for, the waveguide photodiode 602, having the configuration shown in FIG. 7 and with an acute angle 633 of 45°. In contrast, the intensity 804 was determined for a waveguide photodiode having an input facet of an absorbing waveguide that directs refracted light towards an n-doped semiconductor region, and with otherwise the same configuration of the waveguide photodiode 602 of the graph 800. It is further understood that the intensities 802, 804 were both determined using a voltage bias of −1 V. Both waveguide photodiodes were manufactured from silicon and germanium on a PIC.

The graph 800 further includes a line 806 extending horizontally from −3 dB. It is understood that below −3 dB, data encoded in incident light may be challenging to detect. Hence, is it understood that when the intensities 802, 804 of the signals depicted in the graph 800 drop below −3 dB, a respective waveguide photodiode may become non-functional.

For example, a vertical line 808 shows the intersection of the intensity 804 with the line 806 at −3 dB to illustrate that the intensity 804 falls below −3 dB at a bandwidth of 12 GHz, and remains below −3 dB above 12 GHz. Hence, the waveguide photodiode having an input facet of an absorbing waveguide that directs refracted light towards an n-doped semiconductor region is generally non-functional by about 12 GHz.

In contrast, the intensity 802 of the waveguide photodiode 602 is above-3 dB at least until about 40 GHz.

Hence, the graph 800 clearly illustrates that a waveguide photodiode 602 that refracts light towards a p-doped semiconductor region may detect data at a rate greater than about 40 GHz, whereas a waveguide photodiode that refracts light towards an n-doped semiconductor region may stop detecting data at least by about 12 GHz. While this is a specific example, with specific configurations of the waveguide photodiodes used to generate the graph 800, it is understood that the graph 800 illustrates the relative advantages in bandwidth of a waveguide photodiode 602 that refracts light towards a p-doped semiconductor region as compared to a waveguide photodiode that refracts light towards an n-doped semiconductor region.

Advantages in responsivity may also be achieved. For example, attention is next directed to FIG. 9, which depicts a graph 900 of responsivity 902, 904, respectively, of the waveguide photodiode 602, having the configuration shown in FIG. 7 and with an acute angle 633 of 45°, and a waveguide photodiode having an input facet of an absorbing region that is 90° to an optical axis of a main waveguide. Again both such waveguide photodiodes were fabricated from silicon and germanium an integrated in a PIC.

In particular, responsivity may be defined as bandwidth of a particular intensity, such as 3 dB (e.g., as depicted at the graph 900), as a function of current produced by a waveguide photodiode. Comparing the responsivities 902, 904, it is apparent that the waveguide photodiode 602, having the configuration shown in FIG. 7 and with an acute angle 633 of 45° has much better responsivity than a waveguide photodiode having an input facet of an absorbing region that is 90° to an optical axis of a main waveguide. For example, at comparable currents of 1 mA (e.g., as indicated by the line 906), the waveguide photodiode 602, having the configuration shown in FIG. 7 and with an acute angle 633 of 45° achieves a bandwidth of about 50 GHz, whereas the waveguide photodiode having an input facet of an absorbing region that is 90° to an optical axis of a main waveguide achieves a bandwidth of only 20 GHz.

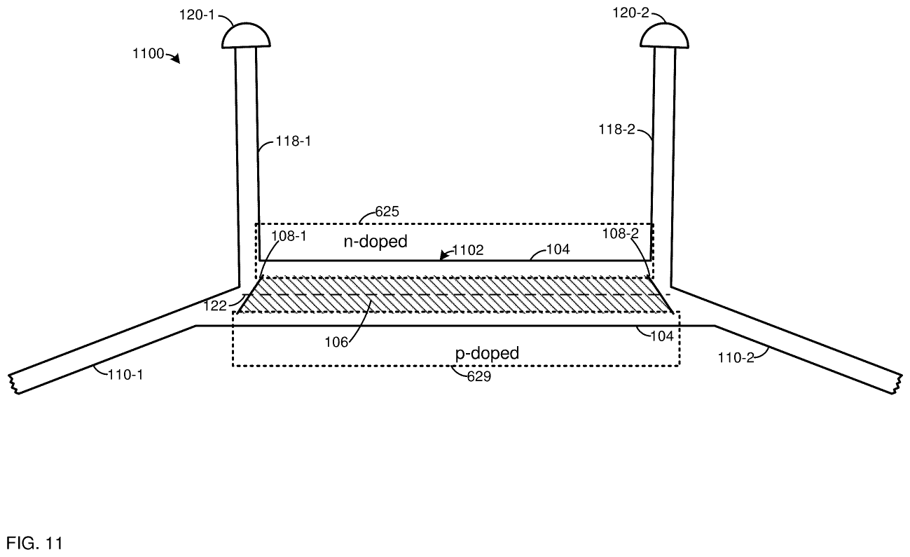

Further alternatives are within the scope of the present specification. For example, attention is next directed to FIG. 11, which depicts another example waveguide photodetector 1100 that comprises a waveguide photodiode 1102, that is similar to a combination of the waveguide photodiode 102 of the waveguide photodetector 300, and the waveguide photodiode 602, with like components having like numbers. For example, the waveguide photodiode 1102 comprises a main waveguide 104 and an absorbing waveguide 106 integrated with the main waveguide 104. However, in contrast to the waveguide photodiode 102 of the waveguide photodetector 300, and/or the waveguide photodiode 602, the waveguide photodiode 1102 includes two input facets 108-1, 108-2 at opposite ends of the waveguide photodiode 1102, for example along an optical axis 122 thereof. Furthermore, the waveguide photodetector 1100 comprises respective input waveguides 110-1, 110-2 located at opposite ends of the waveguide photodiode 1102, as well as respective output waveguides 118-1, 118-2 (and respective light dumps 120-1, 120-2) located at opposite ends of the waveguide photodiode 1102. While for simplicity various angles between the respective input waveguides 110-1, 110-2 and the respective input facets 108-1, 108-2 are not depicted, it is understood that the respective input waveguides 110-1, 110-2 and the respective input facets 108-1, 108-2 have similar geometries to the waveguide photodetector 300 (and/or may be similar to the geometries of the waveguide photodiode 602).

As depicted, the waveguide photodetector 1100 further comprises the n-doped semiconductor region 625 and the p-doped semiconductor region 629 of the waveguide photodiode 602. It is further understood that the geometries of the respective input waveguides 110-1, 110-2 and the respective input facets 108-1, 108-2 direct refracted light at both the input facets 108-1, 108-2 towards the p-doped semiconductor region 629. For clarity, in FIG. 11, the semiconductor region 625, 629 are drawn in broken lines to distinguish the semiconductor regions 625, 629 from other components of the waveguide photodetector 1100.

At the waveguide photodetector 1100, one input waveguide 110-1 may carry light originally in a first polarization state (e.g., TE) and the other input waveguide 110-2 may carry light originally in second polarization state (e.g., TM). For example light transmitted to the waveguide photodetector 1100 may carry two polarization states of an unknown ratio, and a polarization splitting component (not depicted) may split such light into the two polarization states, and convey such light of different polarization states to a respective input waveguide 110-1, 110-2, though light from one of the polarization states (e.g., TM) may be converted to the other polarization state (e.g., TE, and using any suitable polarization converting component, not depicted) before being input to the waveguide photodetector 1100. A length of the waveguide photodiode 1102 (e.g. along the optical axis 122) may be selected such that light refracted into the waveguide photodiode 1102 at one input facet 108 is substantially absorbed by the absorbing waveguide 106, and does not reach the other input facet 108.

It is further understood that any of the waveguide photodetectors and/or waveguide photodiodes provided herein may be adapted in a similar manner as the waveguide photodetector 1100 and/or the waveguide photodiode 1102.

The many features and advantages of the embodiments will be apparent from the description and, thus, it is intended by the appended claims to cover all such features and. Further, since numerous modifications and changes will readily occur to those skilled in the art, it is not desired to limit the embodiments to the exact construction and operation illustrated and described, and accordingly all suitable modifications and equivalents may be resorted to, falling within the scope of the claims.

It is further understood that instance of the term “configured to”, such as “a computing device configured to . . . ”, “a processor configured to . . . ”, “a controller configured to . . . ”, and the like, may be understood to include a feature of a computer-readable storage medium having stored thereon program instructions that, when executed by a computing device and/or a processor and/or a controller, and the like, may cause the computing device and/or the processor and/or the controller to perform a set of operations which may comprise the features that the computing device and/or the processor and/or the controller, and the like, are configured to implement. Hence, the term “configured to” is understood not to be unduly limiting to means plus function interpretations, and the like.

Furthermore, descriptions of one processor and/or controller and/or device and/or engine, and the like, configured to perform certain functionality is understood to include, but is not limited to, more than one processor and/or more than one controller and/or more than one device and/or more than one engine, and the like performing such functionality.

It is understood that for the purpose of this specification, language of “at least one of X, Y, and Z” and “one or more of X, Y and Z” may be construed as X only, Y only, Z only, or any combination of two or more items X, Y, and Z (e.g., XYZ, XY, YZ, XZ, and the like). Similar logic may be applied for two or more items in any occurrence of “at least one . . . ” and “one or more . . . ” language.

The terms “about”, “substantially”, “essentially”, “approximately”, and the like, are defined as being “close to”, for example as understood by persons of skill in the art. In some examples, the terms are understood to be “within 10%,” in other examples, “within 5%”, in yet further examples, “within 1%”, and in yet further examples “within 0.5%”.

Persons skilled in the art will appreciate that there are yet more alternative examples and modifications possible, and that the above examples are only illustrations of one or more examples. The scope, therefore, is only to be limited by the claims appended hereto.

What is claimed is:

1. A waveguide photodetector comprising:
a waveguide photodiode having: a main waveguide, an absorbing waveguide integrated with the main waveguide, and an input facet at the absorbing waveguide; and
an input waveguide for transmitting light to the waveguide photodiode, an input angle between the input waveguide and the input facet comprising an acute interface angle.

2. The waveguide photodetector of claim 1, wherein the acute interface angle is between about 8° and about 65°.

3. The waveguide photodetector of claim 1, wherein the acute interface angle is at a Brewster angle.

4. The waveguide photodetector of claim 1, wherein the input waveguide has a first index of refraction of n1, and the absorbing waveguide has a second index of refraction of n2.

5. The waveguide photodetector of claim 1, further comprising an output waveguide, and an output angle between the output waveguide and the input facet comprises the acute interface angle.

6. The waveguide photodetector of claim 5, further comprising a light dump at an end of the output waveguide opposite to a respective end at the absorbing waveguide.

7. The waveguide photodetector of claim 1, wherein respective optical axes of the input waveguide and the main waveguide are at the acute interface angle, and the input facet is about perpendicular to an optical axis of one or more of the absorbing waveguide and the main waveguide.

8. The waveguide photodetector of claim 1, wherein respective optical axes of the input waveguide and the main waveguide are coincident, and the input facet forms the acute interface angle with a line about perpendicular to an optical axis of one or more of the absorbing waveguide and the main waveguide.

9. The waveguide photodetector of claim 1, wherein the input facet forms an acute angle with a line about perpendicular to an optical axis of one or more of the absorbing waveguide and the main waveguide, the acute angle different from the acute interface angle.

10. The waveguide photodetector of claim 1, wherein the acute interface angle is between an optical axis of the input waveguide and a normal to the input facet.

11. The waveguide photodetector of claim 1, wherein the input waveguide comprises silicon with a dielectric cladding.

12. The waveguide photodetector of claim 1, wherein the main waveguide comprises silicon.

13. The waveguide photodetector of claim 1, wherein the absorbing waveguide comprises germanium.

14. The waveguide photodetector of claim 1, wherein one or more respective corners of one or more of the input waveguide and the main waveguide comprise photolithography compensation structures.
